(19) United States
(12) Patent Application Publication
(10) Pub. No.: US 2025/0106988 A1
(43) Pub. Date: Mar. 27, 2025

(54) FLEXIBLE CIRCUIT BOARD, COF MODULE, AND ELECTRONIC DEVICE COMPRISING SAME

(71) Applicant: LG INNOTEK CO., LTD., Seoul (KR)

(72) Inventors: Seong Woo CHOI, Seoul (KR); Eon Jong LEE, Seoul (KR); Sang Hun PARK, Seoul (KR)

(21) Appl. No.: 18/730,564

(22) PCT Filed: Jan. 11, 2023
(86) PCT No.: PCT/KR2023/000523

§ 371 Date: Jul. 19, 2024

(30) Foreign Application Priority Data
Jan. 19, 2022 (KR) 10-2022-0008061

(51) Int. Cl. H05K 1/02

(52) U.S. Cl. CPC H05K 1/028

(57) ABSTRACT

A flexible circuit board according to an embodiment includes a substrate; a circuit pattern disposed on the substrate; a protective layer on the circuit pattern, wherein the circuit pattern includes a plurality of first circuit patterns and a plurality of second circuit patterns, wherein the plurality of first circuit patterns include a first pattern part and a second pattern part having a minimum length among the plurality of first circuit patterns, wherein the first pattern part includes a first side surface and a second side surface, wherein the first pattern part includes a first bent portion and a second bent portion, and wherein a sum of a length of the first side surface between the first bent portion and the second bent portion and a length of the second side surface between the first bent portion and the second bent portion is 90 μm or more.

### DESCRIPTION

### Technical Field

An embodiment relates to a flexible circuit board, a COF module, and an electronic device including the same. In detail, the flexible circuit board may be a flexible circuit board for COF.

### Background Art

Recently, various electronic products are becoming thinner, smaller, and lighter. Accordingly, research for mounting a semiconductor chip in a narrow region of an electronic product with high density is being conducted.

A chip on film (COF) uses a flexible substrate. Accordingly, the COF may be applied to a flexible display. Therefore, the COF may be applied to various wearable electronic devices. Also, the COF may form a circuit pattern having a fine pitch. Therefore, it may be applied to a high resolution display.

The COF is formed by mounting a semiconductor chip on a flexible circuit board in the form of a thin film. For example, the semiconductor chip may be an Integrated Circuit (IC) chip or a Large Scale Integrated Circuit (LSI) chip.

Meanwhile, the chip may be connected to an external circuit board and a display panel by a circuit pattern. For example, pad parts are disposed at one end and the other end of the circuit pattern, respectively. One pad part is electrically connected to a terminal of the chip. In addition, the other pad part is connected to terminals of the circuit board and the display panel. Accordingly, the chip, the circuit board, and the display panel are electrically connected by the COF. In addition, a signal may be transmitted to the display panel through the circuit pattern.

The COF is applied with a flexible display. Therefore, the flexible circuit board may be bent in one direction.

Thus, cracks may occur in the circuit pattern. Alternatively, the circuit pattern may be separated. Accordingly, electrical characteristics of the flexible circuit board may be deteriorated.

Therefore, a flexible circuit board with a new structure capable of solving the above problems is required.

### DISCLOSURE

### Technical Problem

An embodiment is to provide a flexible circuit board having improved reliability.

### Technical Solution

A flexible circuit board according to an embodiment includes a substrate; a circuit pattern disposed on the substrate; a protective layer on the circuit pattern, wherein the circuit pattern includes a plurality of first circuit patterns and a plurality of second circuit patterns, wherein the plurality of first circuit patterns include a first pattern part and a second pattern part having a minimum length among the plurality of first circuit patterns, wherein the first pattern part includes a first side surface and a second side surface, wherein the first pattern part includes a first bent portion and a second bent portion, and wherein a sum of a length of the first side surface between the first bent portion and the second bent portion and a length of the second side surface between the first bent portion and the second bent portion is 90 μm or more.

### Advantageous Effects

A flexible circuit board according to the embodiment includes a circuit pattern. The circuit pattern includes a region in which the sum of lengths of side surfaces increases.

Specifically, a sum of lengths of both side surfaces of a pattern part having a minimum length among a plurality of circuit patterns may be 90 μm or more.

Accordingly, the strength of the pattern part is improved. That is, since a length of the side surface of the pattern part is increased, a stress moving to the side surface of the pattern part may be reduced.

Therefore, it is possible to prevent cracks from occurring in the pattern part due to the stress.

In addition, a distance between the pattern parts having the minimum length is formed to be greater than a distance between pattern parts having different lengths. Therefore, it is possible to prevent a short circuit from occurring between adjacent pattern parts.

That is, the flexible circuit board according to the embodiment may have improved reliability and driving characteristics.

### DESCRIPTION OF DRAWINGS

FIG. 1 is a view illustrating a top view of a flexible circuit board according to an embodiment.

FIGS. 2 and 3 are cross-sectional views taken along a region A-A′ of FIG. 1.

FIG. 4 is a cross-sectional view taken along a region B-B′ of FIG. 1.

FIG. 5 is an enlarged view illustrating an enlarged view of a region A of FIG. 1.

FIG. 6 is a top view of a COF module according to an embodiment.

FIG. 7 is a cross-sectional view illustrating a connection relationship of a COF module including a flexible printed circuit board according to an embodiment.

FIGS. 8 to 10 are views of an electronic device including a flexible printed circuit board according to an embodiment.

### BEST MODE

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a flexible circuit board, a COF module, and an electronic device including the same according to an embodiment will be described with reference to the drawings.

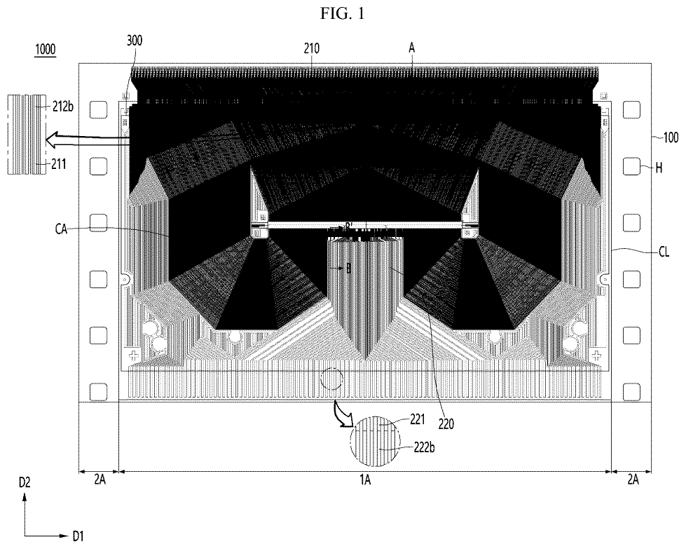

FIG. 1 is a view illustrating a top view of a flexible circuit board according to an embodiment.

Referring to FIG. 1, a flexible circuit board 1000 according to an embodiment includes a substrate 100 and a circuit pattern 200.

The substrate 100 may include a flexible material. For example, the substrate 100 may be a polyimide (PI) substrate. However, the embodiment is not limited thereto. The substrate 100 may include a polymer material such as polyethylene terephthalate (PET) or polyethylene naphthalate (PEN). Accordingly, the flexible circuit board may be applied to various electronic devices including a curved display device. For example, the flexible circuit board may be applied to a wearable electronic device.

A thickness of the substrate 100 may be 20 μm to 100 μm. For example, the thickness of the substrate 100 may be 25 μm to 50 μm. For example, the thickness of the substrate 100 may be 30 μm to 40 μm. When the thickness of the substrate 100 exceeds 100 μm, a thickness of the flexible circuit board may increase. Accordingly, flexible characteristics of the flexible circuit board are reduced. In addition, when the thickness of the substrate 100 is less than 20 μm, heat resistance and durability of the substrate may be reduced. Accordingly, when the chip is mounted on the substrate, the substrate may be damaged.

The substrate 100 may include a first region 1A and a second region 2A. The first region 1A is defined as an effective region. Also, the second region 2A is defined as an invalid region. For example, the first region 1A may be a central region of the substrate 100. Also, the second region 2A may be an edge region of the substrate 100. The second region 2A may surround the first region 1A.

The first region 1A includes a chip mounting region CA. A chip C connected to the circuit pattern is mounted in the chip mounting region CA.

Circuit patterns 210 and 220 are disposed on the first region 1A. The circuit patterns 210 and 220 include a plurality of circuit patterns disposed to be spaced apart from each other. The plurality of circuit patterns extend in multiple directions.

The flexible circuit board is connected to a circuit board and a display panel. In detail, the circuit board and the display panel are connected in the effective region AA.

The circuit pattern may not be disposed in the second region 2A.

The second region 2A may include a plurality of holes. In detail, the second region 2A may include a plurality of sprocket holes H. The flexible circuit board may be wound or unwound by a sprocket hole in a roll-to-roll method.

A boundary between the first region 1A and the second region 2A is defined by a cutting line CL. The flexible circuit board 1000 is cut along the cutting line CL. Accordingly, a COF module is formed.

The substrate 100 includes a first direction D1 and a second direction D2. The first direction D1 is defined in a horizontal direction of the substrate 100. Also, the second direction D2 is defined in a vertical direction of the substrate 100.

Alternatively, the first direction D1 is defined in a width direction of the substrate 100. Also, the second direction D2 is defined in a longitudinal direction of the substrate 100.

The circuit pattern includes a wiring part and a pad part. Also, a plurality of circuit patterns are disposed in the first region 1A. For example, the circuit pattern may include a first circuit pattern 210 and a second circuit pattern 220.

Referring to FIGS. 1 to 3, the first circuit pattern 210 includes a first wiring part 211, a first pad part 212a, and a second pad part 212b. The first pad part 212a is disposed in the chip mounting region CA. The second pad part 212b is disposed outside the chip mounting region CA. The first wiring part 211 is disposed between the first pad part 212a and the second pad part 212b.

The first wiring part 211, the first pad part 212a, and the second pad part 212b are connected to each other. The first wiring part 211, the first pad part 212a, and the second pad part 212b may be integrally formed.

The first pad part 212a is electrically connected to the chip. Furthermore, the second pad part 212b is electrically connected to the display panel. Furthermore, the first wiring part 211 transmits a signal to the chip or the display panel.

A protective layer 300 is disposed on the first circuit pattern 210. The protective layer 300 is disposed on the first wiring part 211. The protective layer 300 may be disposed while surrounding the first wiring part 211. Also, the protective layer 300 is not disposed on the pad parts 212a and 212b. Accordingly, the pad parts 212a and 212b are connected to the chip and the display panel.

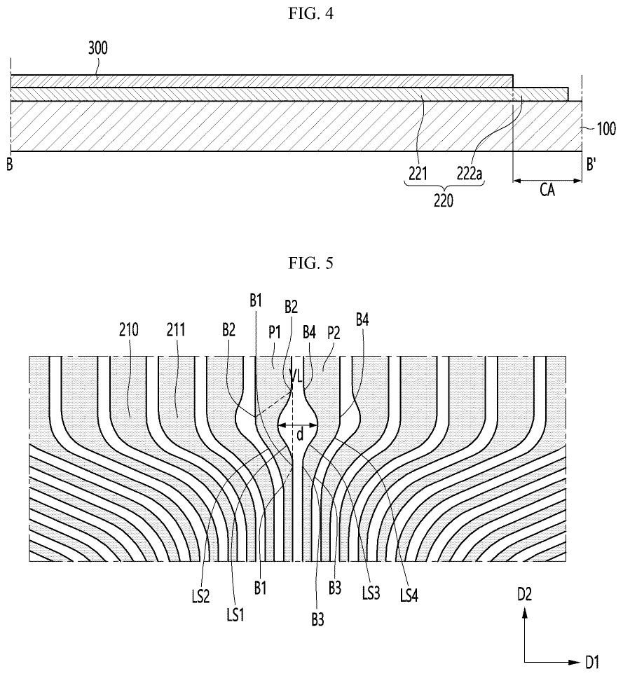

Referring to FIGS. 1 and 4, the second circuit pattern 220 includes a second wiring part 221, a third pad part 222a, and a fourth pad part 222b. The third pad part 222a is disposed in the chip mounting region CA. The fourth pad part 222b is disposed outside the chip mounting region CA. The second wiring part 221 is disposed between the third pad part 222a and the fourth pad part 222b.

The second wiring part 221, the third pad part 222a, and the fourth pad part 222b are connected to each other. The second wiring part 221, the third pad part 222a, and the fourth pad part 222b may be integrally formed.

The third pad part 222a is electrically connected to the chip. Furthermore, the fourth pad part 222b is electrically connected to the circuit board. Furthermore, the second wiring part 221 transmits a signal to the chip or the circuit board.

A protective layer 300 is disposed on the second circuit pattern 220. The protective layer 300 is disposed on the second wiring part 221. The protective layer 300 may be disposed while surrounding the second wiring part 221. Also, the protective layer 300 is not disposed on the pad parts 222a and 222b. Accordingly, the pad parts 222a and 222b are connected to the chip and the circuit board.

The first circuit pattern 210 and the second circuit pattern 220 may include a metal. Specifically, the first circuit pattern 210 and the second circuit pattern 220 may include copper (Cu). However, the embodiment is not limited thereto. The first circuit pattern 210 and the second circuit pattern 220 may include at least one of copper (Cu), aluminum (Al), chromium (Cr), nickel (Ni), silver (Ag), molybdenum (Mo). Gold (Au), titanium (Ti), and alloys thereof.

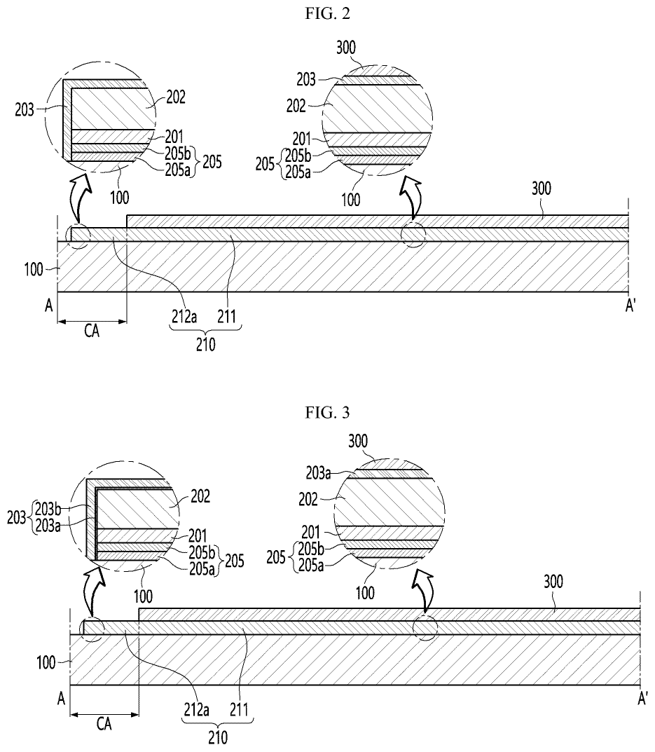

Hereinafter, a layer structure of a circuit pattern of a flexible circuit board according to an embodiment will be described. In FIGS. 2 and 3, the first circuit pattern 210 will be mainly described. However, a description of the layer structure described in FIGS. 2 and 3 may be equally applied to the second circuit pattern 220.

Referring to FIG. 2, the first circuit pattern 210 may be formed in multiple layers. Specifically, the first wiring part 211 and the first pad part 212a may include a first metal layer 201 and a second metal layer 202. Also, the second pad part 212b may include the first metal layer 201 and the second metal layer 202.

The first metal layer 201 may be a seed layer of the first circuit pattern 210. For example, the first metal layer 201 may be a seed layer formed by electroless plating using copper (Cu) and disposed on the substrate 100.

Also, the second metal layer 202 may be a plating layer. In detail, the second metal layer 202 may be a plating layer formed by electroplating using the first metal layer 201 as a seed layer.

A thickness of the first metal layer 201 may be less than a thickness of the second metal layer 202.

For example, a thickness of the first metal layer 201 may be 0.7 μm to 2 μm. Also, a thickness of the second metal layer 202 may be 10 μm to 25 μm.

The first metal layer 201 and the second metal layer 202 may include the same metal material. For example, the first metal layer 201 and the second metal layer 202 may include copper (Cu).

A bonding layer 203 may be disposed on the second metal layer 201. The bonding layer 203 may be disposed on a side surface of the first metal layer 201, a side surface of the second metal layer 202, and an upper surface of the second metal layer 202. That is, the bonding layer 203 may be disposed while surrounding the first metal layer 201 and the second metal layer 202.

The bonding layer 203 may include a metal. In detail, the bonding layer 203 may include tin (Sn).

A thickness of the bonding layer 203 may be 0.3 μm to 0.7 μm. A content of tin in the bonding layer increases while extending in a direction from a lower surface to an upper surface. The lower surface is a surface where the bonding layer 203 and the second metal layer 202 contact each other.

The bonding layer 203 contacts the second metal layer 202. Accordingly, a content of tin in the bonding layer increases while extending in a direction from a lower surface to an upper surface. Also, a content of copper decreases.

Accordingly, only pure tin may remain in a thickness range of 0.1 μm to 0.3 μm on the upper surface of the bonding layer 203.

A terminal of the chip, a terminal of the printed circuit board, and a terminal of the display panel may be easily adhered to the first pad part and the second pad part by the bonding layer 203. That is, when heat and pressure are applied to the first pad part and the second pad part, the upper surface of the bonding layer in which pure tin remains is melted. Accordingly, the terminal of the chip, the terminal of the printed circuit board, and the terminal of the display panel may be easily adhered to the first pad part and the second pad part.

Accordingly, the bonding layer 203 is not separated from the first pad part 212a. That is, the bonding layer 203 becomes a part of the first pad part 212a.

The first circuit pattern 210 may have a thickness of 2 μm to 25 μm. For example, the first circuit pattern 210 may have a thickness of 5 μm to 20 μm. For example, the first circuit pattern 210 may have a thickness of 7 μm to 15 μm.

A process of manufacturing the first circuit pattern 210 includes flash etching. The circuit patterns are spaced apart by the flash etching. The first metal layer 201 is etched by the flash etching. Therefore, the thickness of the finally manufactured first circuit pattern 210 may be less than the sum of the thicknesses of the first metal layer 201, the second metal layer 202, and the bonding layer 203 formed during the manufacturing process.

When the thickness of the first circuit pattern 210 is less than 2 μm, the resistance of the first circuit pattern 210 may increase. When the thickness of the first circuit pattern 210 is more than 25 μm, it is difficult to form a fine pattern.

A buffer layer 205 may be disposed between the substrate 100 and the first circuit pattern 210. The adhesion between the substrate 100 and the first circuit pattern 210 may be improved by the buffer layer 205.

The buffer layer 205 may be formed of multiple layers. Specifically, the buffer layer 205 may include a first buffer layer 205a and a second buffer layer 205b on the first buffer layer 205a. The first buffer layer 205a is in contact with the substrate 100. Furthermore, the second buffer layer 205b is in contact with the first circuit pattern 201.

The first buffer layer 205a may include a material that has excellent adhesion to the substrate 100. For example, the first buffer layer 205a may include nickel (Ni). Also, the second buffer layer 205b may include a material that has excellent adhesion to the first circuit pattern 210. For example, the second buffer layer 205b may include chromium (Cr).

The buffer layer 205 may have a thin film thickness of nanometers or less. For example, the thickness of the buffer layer 205 may be 20 nm or less.

The adhesion between the substrate 100 and the first circuit pattern 210 is enhanced by the buffer layer 205. Therefore, it is possible to prevent the first circuit pattern 201 from being delaminated.

Referring to FIG. 3, the bonding layer 203 may include a first bonding layer 203a and a second bonding layer 203b.

Specifically, the first bonding layer 203a may be disposed on the first wiring part 211 and the first pad part 212a. Also, the first bonding layer 203a may be disposed on the second pad part 212b. That is, the first bonding layer 203a may be disposed on the first circuit pattern 210.

Furthermore, the second bonding layer 203b may be disposed only on the first pad part 212a and the second pad part 212b. That is, the first wiring part 211 may have a layer structure different from that of the first pad part 212a and the second pad part 212b by the second bonding layer 203b.

The first bonding layer 203a and the second bonding layer 203b may include metal. In detail, the first bonding layer 203a and the second bonding layer 203b may include tin (Sn).

The first bonding layer 203a and the second bonding layer 203b may be disposed to have different thicknesses. Specifically, the thickness of the second bonding layer 203b may be greater than that of the first bonding layer 203a.

For example, a thickness of the first bonding layer 203a may be in a range of 0.02 μm to 0.06 μm. Also, a thickness of the second bonding layer 203b may be in a range of 0.2 μm to 0.6μm.

When the bonding layer between the protective layer 300 and the first wiring part 211 is thickly disposed, cracks may occur when the flexible circuit board is bent. Accordingly, the first bonding layer 231 between the protective layer 300 and the first wiring part 211 is formed to have a thin thickness. Accordingly, cracks may be prevented from occurring when the flexible circuit board is bent.

Also, a content of tin in the second bonding layer 203b may increase while extending in a direction from a lower surface to an upper surface. The lower surface is a surface where the second bonding layer 203b and the first bonding layer 203a contact each other.

That is, the content of tin in the second bonding layer 203b increases and the content of copper tin in the second bonding layer 203b decreases while extending in a direction from a lower surface to an upper surface.

Accordingly, only pure tin may remain in the thickness range of 0.1 μm to 0.3 μm on the upper surface of the second bonding layer 203b.

The terminal of the chip, the terminal of the printed circuit board, and the terminal of the display panel may be easily adhered to the first pad part and the second pad part by the second bonding layer 203b. That is, when heat and pressure are applied to the first pad part and the second pad part, the upper surface of the bonding layer in which pure tin remains is melted. Accordingly, the terminal of the chip, the terminal of the printed circuit board, and the terminal of the display panel may be easily adhered to the first pad part and the second pad part.

Accordingly, the first bonding layer 203a and the second bonding layer 203b are not separated from the first pad part 212a. That is, the first bonding layer 203a and the second bonding layer 203b become a part of the first pad part 212a.

The protective layer 300 may include a solder paste. For example, the solder paste may include a thermosetting resin, a thermoplastic resin, a filler, a curing agent, or a curing accelerator.

Meanwhile, in the previous description, it has been described that the first circuit pattern 210 and the second circuit pattern 220 are disposed on the same surface of the substrate 100. However, embodiments are not limited thereto.

Specifically, the first circuit pattern 210 and the second circuit pattern 220 may be disposed on the other surface of the substrate 100. For example, the first circuit pattern 210 may be disposed on one surface of the substrate 100, and the second circuit pattern 220 may be disposed on the other surface opposite to one surface of the substrate 100.

Accordingly, the display panel is connected to the chip on one surface of the substrate 100. In addition, the circuit board may be connected to the chip on the other surface of the substrate 100.

FIG. 5 is an enlarged view of a region A of FIG. 1.

Referring to FIGS. 1 and 5, the first circuit pattern 210 includes a plurality of first circuit patterns. A plurality of first circuit patterns 210 extend in a plurality of directions. Specifically, a plurality of first wiring parts 211 extend in a plurality of directions.

The first wiring part 211 may extend in at least one direction while being connected to the first pad part 212a and the second pad part 212b.

Accordingly, a plurality of first circuit patterns 210 may have different lengths. That is, the plurality of first circuit patterns 210 may have different lengths according to the degree of bending.

Among a plurality of first circuit patterns, a pattern part having a minimum length may be defined. Specifically, the first circuit pattern 210 may include a first pattern part P1 and a second pattern part P2 having a minimum length.

Each of the first pattern part P1 and the second pattern part P2 may correspond to any one of the plurality of first wiring parts 211.

That is, a length of the first pattern part P1 and a length of the second pattern part P2 may be smaller than a length of another first wiring part. Also, lengths of the first pattern part P1 and the second pattern part P2 may be the same or similar.

The first pattern part P1 and the second pattern part P2 are disposed adjacent to each other. The first pattern part P1 and the second pattern part P2 are disposed to face each other. For example, the first pattern part P1 and the second pattern part P2 may face each other in a longitudinal direction of the substrate 100.

The first pattern part P1 may include a first side surface LS1 and a second side surface LS2. The first side surface LS1 is closer to a central portion of the flexible circuit board than the second side surface LS2. A distance between the first side surface LS1 and the second side surface LS2 is defined as a width of the first pattern part P1.

The first side surface LS1 and the second side surface LS2 face each other. Also, the first side surface LS1 faces the second pattern part P2.

The first pattern part P1 includes a first bent portion B1 and a second bent portion B2.

The first bent portion B1 and the second bent portion B2 are defined as areas where a straight line is bent into a curved line.

Alternatively, the first bent portion B1 and the second bent portion B2 are defined as a region bent in the second direction or the third direction. The third direction is defined in a direction different from the first direction and the second direction.

For example, the first bent portion B1 is a region bent in the second direction D2 from the third direction. Also, the second bent portion B2 is a region bent in the third direction from the second direction.

The first bent portion B1 and the second bent portion B2 are defined as points at which the first pattern part P1 starts to be bent. For example, the second bent portion B2 is defined as a point at which bending starts for a first time in a region from the second pad part 212b to the first pad part 212a. Furthermore, the first bent portion B1 is defined as a point at which bending starts for a second time in a region from the second pad part 212b to the first pad part 212a. That is, the first pattern part P1 is bent in a direction different from that of the first bent portion B1. Furthermore, the first pattern part P1 is bent in a direction different from that of the second bent portion B2.

Accordingly, the first side surface LS1 and the second side surface LS2 include a first bent portion B1 and a second bent portion B2, respectively.

A first side surface and a second side surface between the first bent portion B1 and the second bent portion B2 are defined. A sum of lengths of the first side surface and the second side surface between the first bent portion B1 and the second bent portion B2 may have a set range.

Specifically, the sum of lengths of the first side surface and the second side surface between the first bent portion B1 and the second bent portion B2 may be 90 μm, 100 μm, or 120 μm or more. Accordingly, cracks of the first circuit pattern 210 may be prevented.

Specifically, the flexible circuit board may be bent in one of regions in which the first circuit pattern 210 extends. As the flexible circuit board is bent, stress is generated. The stress is transferred to the first circuit pattern. Accordingly, cracks may be generated in the first circuit pattern. In particular, a first pattern part having a minimum length among the first circuit patterns 210 may be damaged by the stress.

Accordingly, in the flexible circuit board according to an embodiment, a sum of lengths of side surface of the first pattern part is formed within a set range. Accordingly, cracks may be prevented from being provided in the first circuit pattern due to the stress.

That is, the first pattern part has a plurality of bent portions. The sum of the lengths of the side surface of the first pattern part is increased by the bent portion. Accordingly, a magnitude of the stress moving along the side surface of the first pattern part may be reduced. That is, the sum of the side lengths of the first pattern part is increased. Accordingly, the stress per length of the first pattern part decreases. Accordingly, the magnitude of the stress transmitted to the first pattern part may be reduced.

Accordingly, the flexible circuit board according to an embodiment may prevent damage to a circuit pattern due to stress. Accordingly, reliability may be improved.

A length of a first side surface between the first bent portion and the second bent portion may be different from a length of a second side surface between the first bent portion and the second bent portion. Specifically, a curvature size of the first side surface LS1 may be different from a curvature size of the second side surface LS2. Accordingly, a length of a first side surface between the first bent portion and the second bent portion may be greater than a length of a second side surface between the first bent portion and the second bent portion.

In addition, a difference between a length of the first side surface between the first bent portion and a length of the second side surface between the first bent portion and the second bent portion may have a set range.

For example, the length of the first side surface between the first bent portion and the second bent portion may be greater than the length of the second side surface between the first bent portion and the second bent portion. The length of the second side surface between the first bent portion and the second bent portion may be 80% or more of the length of the first side surface between the first bent portion and the second bent portion.

Specifically, the length of the second side surface between the first bent portion and the second bent portion may be 80% to 95% of the length of the first side surface between the first bent portion and the second bent portion.

When the length of the second side surface between the first bent portion and the second bent portion exceeds 95% of the length of the first side surface between the first bent portion and the second bent portion, process efficiency may be reduced. In addition, when the length of the second side surface between the first bent portion and the second bent portion is less than 80% of the length of the first side surface between the first bent portion and the second bent portion, the magnitude of stress per length transmitted to the first side surface LS1 and the second side surface LS2 becomes non-uniform. As a result, a crack may occur in the first pattern part.

A width of the first pattern part P1 may be changed while extending in one direction. Specifically, the width of the first pattern part P1 may change while extending in a direction from the first bent portion B1 toward the second bent portion B2. For example, the first pattern part P1 may include a region whose width is widened while extending in a direction from the first bent portion B1 toward the second bent portion B2. In addition, the first pattern part P1 may include a region whose width is narrowed while extending from the first bent portion B1 toward the second bent portion B2.

The first side surface LS1 and the second side surface LS2 may each include a bent portion. The first bent portion of the first side surface LS1 and the first bent portion of the second side surface LS2 may be disposed to be misaligned with each other.

In detail, the first bent portion of the first side surface LS1 and the first bent portion of the second side surface LS2 may face each other in a direction different from a width direction of the first pattern part P1.

In addition, the second bent portion of the first side surface LS1 and the second bent portion of the second side surface LS2 may face each other in a direction different from the width direction of the first pattern part P1.

Accordingly, the first pattern part P1 may be formed in various shapes. In addition, the first pattern part P1 may be formed in various sizes.

Therefore, it is possible to prevent cracks from occurring in the first pattern part P1 due to an error in a position where the flexible circuit board is bent.

A shape of the first pattern part P1 may be concave. In detail, the first side surface LS1 of the first pattern part P1 may be concave toward the second side surface LS2.

In addition, an imaginary line extending from the first bent portion may be defined. In detail, an imaginary line VL extending from the first bent portion toward the second bent portion may be defined.

A distance between the first side surface LS1 and the imaginary line VL may be different for each position. In detail, the first pattern part P1 may include a region in which a distance between the first side surface LS1 and the imaginary line VL increases. Also, the first pattern part P1 may include a region in which the distance between the first side surface LS1 and the imaginary line VL decreases.

That is, the distance between the first side surface LS1 and the imaginary line VL may increase and then decrease.

Accordingly, the distance between the first pattern part and the pattern part adjacent to each other may be increased. Therefore, it is possible to prevent the pattern parts from being short-circuited in the region in which the width of the first pattern part changes.

The second pattern part P2 may include a plurality of side surfaces and bent portions similar to the first pattern part P1 described above.

In detail, the second pattern part P2 includes a third side surface LS3 and a fourth side surface LS4. The third side surface LS3 is closer to a central portion of the flexible circuit board than the fourth side surface LS4. A distance between the third side surface LS3 and the fourth side surface LS4 is defined as a width of the second pattern part P2.

The third side surface LS3 and the fourth side surface LS4 face each other. Also, the third side surface LS3 faces the first pattern part P1. That is, the third side surface LS3 faces the first side surface LS1 of the first pattern part P1.

The second pattern part P2 includes a third bent portion B3 and a fourth bent portion B4. The third bent portion B3 and the fourth bent portion B4 are defined as points at which the bending of the second pattern part P2 starts. For example, the fourth bent portion B4 is defined as a point at which the bending starts for the first time in a region from the second pad part 212b to the first pad part 212a. Also, the third bent portion B3 is defined as a point at which the bending starts for a second time in a region from the second pad part 212b to the first pad part 212a of the second pattern part P2.

That is, the second pattern part P2 is bent in a different direction from the third bent portion B3. In addition, the second pattern part P2 is bent in a different direction from the fourth bent portion B4.

Accordingly, the third side surface LS3 and the fourth side surface LS4 include a third bent portion B3 and a fourth bent portion B4, respectively.

A sum of the length of the first side surface between the third bent portion B3 and the fourth bent portion B4 and the length of the second side surface between the third bent portion and the fourth bent portion is the same as or similar to a description of the first pattern part.

In addition, a difference between the length of the third side surface between the third bent portion and the fourth bent portion and the length of the fourth side surface between the third bent portion and the fourth bent portion is the same as or similar to the description of the first pattern part.

Also, a change in the width of the second pattern part is the same as or similar to the description of the first pattern part.

In addition, a shape of the second pattern part and the arrangement of the third and fourth bent portions are the same as or similar to the description of the first pattern part.

Therefore, the following description is omitted.

The first pattern part P1 and the second pattern part P2 are spaced apart from each other. Accordingly, a distance d between the first pattern part P1 and the second pattern part P2 is defined as a distance between the first side surface LS1 of the first pattern part P1 and the third side surface LS3 of the second pattern part P2.

The distance d may be changed while extending in one direction.

For example, the distance between the first side surface LS1 and the third side surface LS3 may include a region that increases while extending from the first bent portion toward the second bent portion. Alternatively, the distance between the first side surface LS1 and the third side surface LS3 may include a region that increases while extending from the third bent portion toward the fourth bent portion.

Alternatively, the distance between the first side surface LS1 and the third side surface LS3 may include a region that increases and decreases while extending from the first bent portion toward the second bent portion. Alternatively, the distance between the first side surface LS1 and the third side surface LS3 may include a region that increases and decreases while extending from the third bent portion toward the fourth bent portion.

Also, a maximum distance between the first side surface LS1 and the third side surface LS3 may be greater than a maximum distance of other regions.

For example, the maximum distance between the first side surface LS1 and the third side surface LS3 between the first bent portion and the second bent portion may be greater than a distance between the second pad part of the first pattern part P1 and the second pad part of the second pattern part P2.

That is, the distance between the first pattern part P1 and the second pattern part P2 may have a size greater in a region including bent portions than in other regions.

Accordingly, it is possible to prevent the first pattern part and the second pattern part from being short-circuited by the bent portions.

A flexible circuit board according to the embodiment includes a circuit pattern. The circuit pattern includes a region in which the sum of lengths of side surfaces increases.

Specifically, a sum of lengths of both side surfaces of a pattern part having a minimum length among a plurality of circuit patterns may be 90 μm or more.

Accordingly, the strength of the pattern part is improved. That is, since a length of the side surface of the pattern part is increased, a stress moving to the side surface of the pattern part may be reduced.

Therefore, it is possible to prevent cracks from occurring in the pattern part due to the stress.

In addition, a distance between the pattern parts having the minimum length is formed to be greater than a distance between pattern parts having different lengths. Therefore, it is possible to prevent a short circuit from occurring between adjacent pattern parts.

That is, the flexible circuit board according to the embodiment may have improved reliability and driving characteristics.

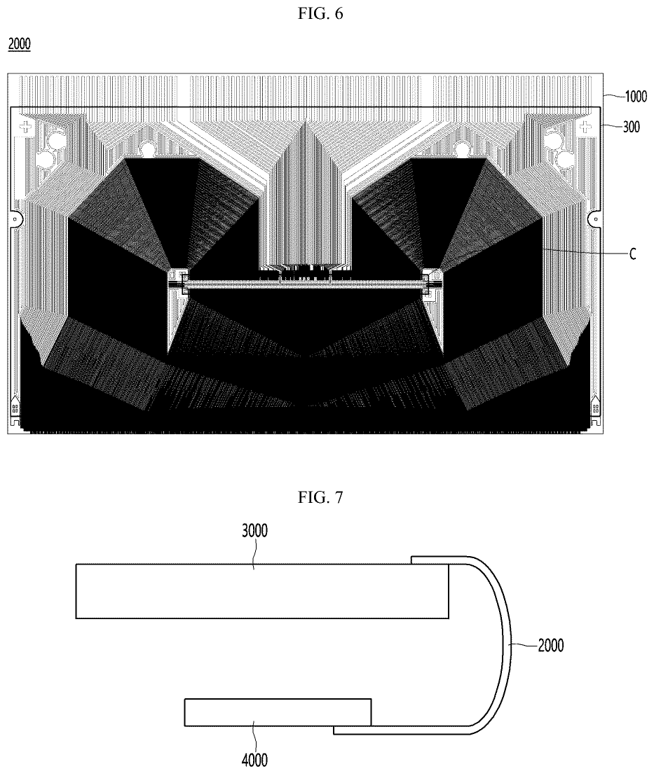

FIG. 6 is a top view of a COF module according to an embodiment.

Referring to FIG. 6, the COF module according to an embodiment includes the flexible circuit board described above. Also, the chip C is disposed in the chip mounting region CA. Also, the flexible circuit board 1000 includes the protective layer 300.

The COF module is connected to the display panel and the circuit board. In addition, the COF module may transmit signals.

Referring to FIG. 7, one end of the COF module 2000 is connected to a display panel 3000 according to an embodiment. Also, the other end of the COF module 2000 is connected to a circuit board 4000.

For example, the COF module 2000 and the display panel 3000 are electrically connected through an anisotropic conductive film. Furthermore, the COF module 2000 and the circuit board 4000 are electrically connected through anisotropic conductive film.

The COF module 1000 includes a flexible substrate. Therefore, it may be bent between the display panel 3000 and the printed circuit board 4000. Therefore, the thickness of the electronic device may be reduced. Also, even when the COF module 2000 is bent, cracks may be prevented from occurring in a circuit pattern. Therefore, the reliability of the electronic device may be improved.

Since the COF module is flexible, it can be used in various electronic devices.

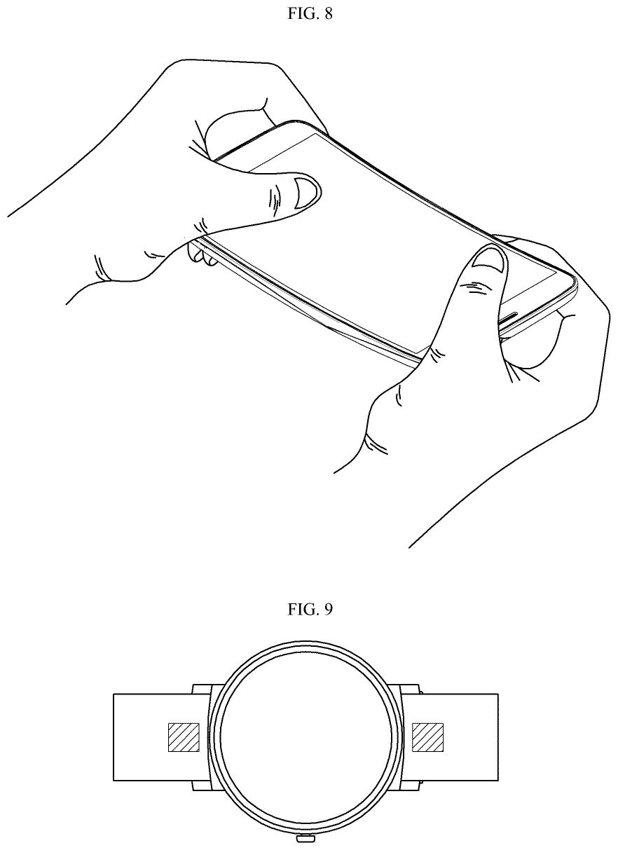

For example, referring to FIG. 8, the COF module may be applied to a flexible touch window. The touch window is applied to a flexible touch device. Thus, the user may bend the touch device.

Referring to FIG. 9, the COF module may be applied to various wearable touch devices. Therefore, the wearable touch device may be slimmed or lightweight.

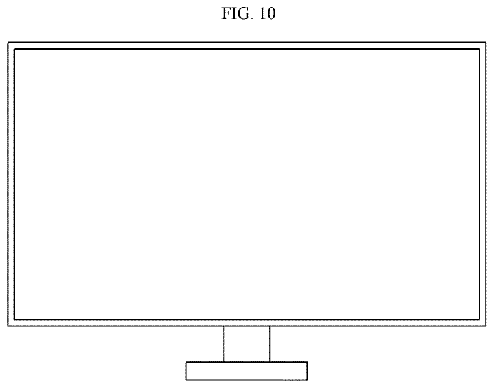

Referring to FIG. 10, the COF module may be applied to various electronic devices such as a TV, a monitor, and a notebook computer.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A flexible circuit board comprising:
a substrate;
a circuit pattern disposed on the substrate; and
a protective layer disposed on the circuit pattern,
wherein the substrate includes a first side end and a second side end facing each other,
wherein the circuit pattern includes a plurality of first circuit patterns extending toward the first side end and having different lengths;
wherein the plurality of first circuit patterns include a first pattern part having a minimum length,
wherein the first pattern part includes a first bent portion and a second bent portion,
wherein a sum of a length of a first side surface of the first pattern part between the first bent portion and the second bent portion and a length of a second side surface of the first pattern part opposite of the first side surface between the first bent portion and the second bent portion is 90 μm or more.

2. The flexible circuit board of claim 1, wherein the length of the first side surface between the first bent portion and the second bent portion is different from the length of the second side surface between the first bent portion and the second bent portion.

3. The flexible circuit board of claim 1, wherein the length of the second side surface between the first bent portion and the second bent portion is 80% to 95% of the length of the first side surface between the first bent portion and the second bent portion.

4. The flexible circuit board of claim 1, wherein a width of the first pattern part changes while extending from the first bent portion to the second bent portion.

5. The flexible circuit board of claim 1, wherein a curvature of the first bent portion in the first side surface or the second side surface is different from that of the second bent portion in the first side surface or the second side surface.

6. The flexible circuit board of claim 1, wherein a first bent portion of the first side surface and a first bent portion of the second side surface face each other in a direction different from a width direction of the first pattern part, and
wherein a second bent portion of the first side surface and a second bent portion of the second side surface face each other in a direction different from the width direction of the first pattern part.

7. The flexible circuit board of claim 1, wherein the first side surface is disposed closer to a central portion of the substrate than the second side surface, and
wherein the first side surface is concave toward the second side surface.

8. The flexible circuit board of claim 7, wherein the first pattern part includes an imaginary line connecting the first bent portion of the first side surface and the second bent portion of the first side surface, and
wherein a distance between the first side surface and the imaginary line increases and then decreases.

9. The flexible circuit board of claim 1, wherein the first circuit pattern includes a second pattern part including a third side surface facing the first side surface of the first pattern part and a fourth side surface opposing the third side surface, and
wherein a distance between the first pattern part and the second pattern part includes a region in which the width is increased while extending from the first bent portion toward the second bent portion.

10. The flexible circuit board of claim 1,
wherein the second pattern part includes a third bent portion and a fourth bent portion,
wherein the first side surface is disposed closer to a central portion of the substrate than the second side surface,
wherein the third side surface is disposed closer to the central portion of the substrate than the fourth side surface, and
wherein a distance between the first side surface and the third side surface includes a region that increases while extending from the first bent portion toward the second bent portion.

11. The flexible circuit board of claim 1, wherein each of the first bent portion and the second bent portion is defined as a point at which the first side surface and the second side surface of the first pattern part start to bend from a straight line to a curved line.

12. The flexible circuit board of claim 1, wherein each of the first bent portion and the second bent portion is defined as a point in which a direction in which the first side surface and the second side surface of the first pattern part extend is changed.

13. The flexible circuit board of claim 10, wherein a maximum distance between the first side surface and the third side surface at the first bent portion and the second bent portion is greater than a distance between a pad part of the first pattern part and a pad part of the second pattern part.

14. The flexible circuit board of claim 10, wherein the first pattern part and the second pattern part have a symmetrical shape with respect to a center portion of the substrate.

15. The flexible circuit board of claim 10, wherein the first side surface and the third side surface have a symmetrical shape with respect to a center portion of the substrate.

16. The flexible circuit board of claim 15, wherein the second side surface and the fourth side surface have a symmetrical shape with respect to a center portion of the substrate.

17. A COF module comprising:
a flexible circuit board including a chip mounting region; and
a chip disposed in the chip mounting region of the flexible circuit board,
wherein the flexible circuit board includes:
a substrate; and
a circuit pattern disposed on the substrate and extending from the chip mounting region toward a side end of the substrate,
wherein the circuit pattern includes a plurality of pattern parts having different lengths;
wherein a first pattern part having a minimum length among the plurality of pattern parts includes a first bent portion and a second bent portion,
wherein a sum of a length of a first side surface of the first pattern part between the first bent portion and the second bent portion and a length of a second side surface of the first pattern part opposite of the first side surface between the first bent portion and the second bent portion is 90 μm or more.

18. The COF module of claim 17, wherein each of the first bent portion and the second bent portion is defined as a point at which the first side surface and the second side surface of the first pattern part start to bend from a straight line to a curved line, or a point in which a direction in which the first side surface and the second side surface of the first pattern part extend is changed.

19. The COF module of claim 17, wherein a length of the first side surface between the first bent portion and the second bent portion is different from a length of the second side surface between the first bent portion and the second bent portion.

20. The COF module of claim 17, wherein a width of the first pattern part changes while extending from the first bent portion to the second bent portion, and
wherein a curvature of the first bent portion in the first side surface or the second side surface is different from a curvature of the second bent portion in the first side surface or the second side surface.
